(19) United States
(12) Patent Application Publication
(10) Pub. No.: US 2020/0083098 A1
(43) Pub. Date: Mar. 12, 2020

(54) Embedding Method and Processing System

(71) Applicant: TOKYO ELECTRON LIMITED, Tokyo (JP)

(72) Inventors: Kohichi SATOH, Nirasaki City (JP); Tadahiro ISHIZAKA, Nirasaki City (JP)

(21) Appl. No.: 16/556,977

(22) Filed: Aug. 30, 2019

(30) Foreign Application Priority Data
Sep. 6, 2018 (JP) 2018-167232

(51) Int. Cl. H01L 21/768; C23C 16/06; C23C 16/46; C23C 16/02

(52) U.S. Cl. CPC H01L 21/76877; C23C 16/0227; C23C 16/46; C23C 16/06

(57) ABSTRACT

An embedding method includes: supplying a ruthenium-containing gas to a process chamber; and embedding ruthenium in a recess, which is formed in an insulating layer formed on a substrate, starting from a bottom portion of the recess using the ruthenium-containing gas, the bottom portion of the recess having a metal layer.

### CROSS-REFERENCE TO RELATED APPLICATION

This application is based upon and claims the benefit of priority from Japanese Patent Application No. 2018-167232, filed on Sep. 6, 2018, the entire contents of which are incorporated herein by reference.

### TECHNICAL FIELD

The present disclosure relates to an embedding method and a processing system.

### BACKGROUND

A process is known in which a metal material such as ruthenium is embedded in, for example, a recess such as a trench, a via hole, or a contact hole provided in an insulating layer.

Patent Document 1 discloses a method of manufacturing a semiconductor device having a process of forming a ruthenium film or a ruthenium oxide film on a substrate using a gas obtained by vaporizing a ruthenium liquid source and an oxygen-containing gas.

### PRIOR ART DOCUMENT

### Patent Document

Patent Document 1: Japanese laid-open publication No. 2008-22021

### SUMMARY

An aspect of the present disclosure provides an embedding method including: supplying a ruthenium-containing gas to a process chamber; and embedding ruthenium in a recess, which is formed in an insulating layer formed on a substrate, starting from a bottom portion of the recess using the ruthenium-containing gas, the bottom portion of the recess having a metal layer.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a schematic plan view illustrating an example of a processing system for use in an embedding method according to an embodiment.

FIG. 2 is a vertical sectional view illustrating an example of a process chamber used for an embedding method according to an embodiment.

FIG. 3 illustrates an example of selection ratios when ruthenium is embedded according to an embodiment.

FIGS. 4A to 4C are schematic sectional views of a wafer illustrating respective processes of an embedding method according to the embodiment.

FIG. 5 illustrates presence and absence of a pre-cleaning process and an example of selection ratios according to a modification of an embodiment.

FIGS. 6A to 6D are schematic sectional views of a wafer illustrating respective processes of an embedding method according to the modification of the embodiment.

FIGS. 7A to 7D are schematic sectional views of a wafer W illustrating respective processes of an embedding method according to a first comparative example.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, embodiments of the present disclosure will be described with reference to the accompanying drawings. In each of the drawings, the same components are denoted by the same reference numerals, and redundant descriptions may be omitted.

### <Processing System>

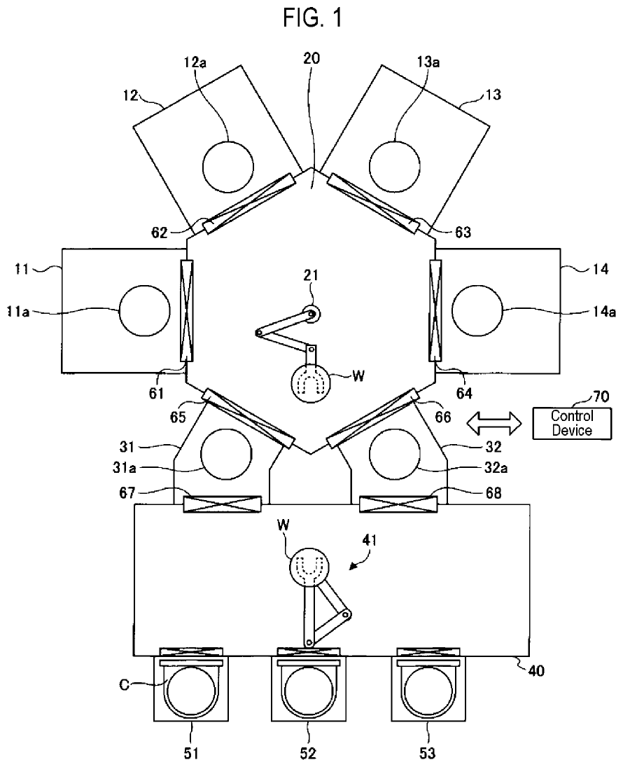

First, a processing system for use in an embedding method according to an embodiment will be described with reference to FIG. 1. FIG. 1 is a schematic plan view illustrating an example of a processing system for use in an embedding method according to an embodiment.

The processing system includes process chambers 11 to 14, a vacuum transfer chamber 20, load-lock chambers 31 and 32, an atmospheric transfer chamber 40, load ports 51 to 53, gate valves 61 to 68, and a control device 70.

The process chamber 11 has a stage 11a configured to place a semiconductor wafer W (hereinafter referred to as “wafer W”) thereon, and is connected to the vacuum transfer chamber 20 via the gate valve 61. Similarly, the process chamber 12 has a stage 12a configured to place a wafer W thereon, and is connected to the vacuum transfer chamber 20 via the gate valve 62. The process chamber 13 has a stage 13a configured to place a wafer W thereon, and is connected to the vacuum transfer chamber 20 via the gate valve 63. The process chamber 14 has a stage 14a configured to place a wafer W thereon, and is connected to the vacuum transfer chamber 20 via the gate valve 64. The interior of the process chambers 11 to 14 are depressurized to predetermined vacuum atmospheres, and desired processes (e.g., an etching process, a film-forming process, a cleaning process, an ashing process, and the like) are performed on wafers W in the interiors of the process chambers 11 to 14. Operations of respective components for performing the processes in the process chambers 11 to 14 are controlled by the control device 70.

The interior of the vacuum transfer chamber 20 is depressurized to a predetermined vacuum atmosphere. In addition, a transfer mechanism 21 is provided in the vacuum transfer chamber 20. The transfer mechanism 21 transfers the wafers W to the process chambers 11 to 14 and to the load-lock chambers 31 and 32. Operation of the transfer mechanism 21 is controlled by the control device 70.

The load-lock chamber 31 has a stage 31a configured to mount a wafer W thereon, is connected to the vacuum transfer chamber 20 via the gate valve 65, and is connected to the atmospheric transfer chamber 40 via the gate valve 67. Similarly, the load-lock chamber 32 has a stage 32a configured to mount a wafer W thereon, is connected to the vacuum transfer chamber 20 via the gate valve 66, and is connected to the atmospheric transfer chamber 40 via the gate valve 68. The interior of each of the load-lock chambers 31 and 32 is configured to be switchable between an atmospheric atmosphere and a vacuum atmosphere. In addition, the switching between the vacuum atmosphere and the atmospheric atmosphere in each of the load-lock chambers 31 and 32 is controlled by the control device 70.

The interior of the atmosphere transfer chamber 40 is kept in an atmospheric atmosphere, and a downflow of, for example, clean air is formed in the atmosphere transfer chamber 40. In addition, a transfer mechanism 41 is provided in the vacuum transfer chamber 40. The transfer mechanism 41 transfers the wafers W to the load-lock chambers 31 and 32 and to carriers C in the load ports 51 to 53 described later. Operation of the transfer mechanism 41 is controlled by the control device 70.

The load ports 51 to 53 are provided on a long side wall of the atmospheric transfer chamber 40. A carrier C in which wafers W are accommodated or an empty carrier C is mounted in each of the load ports 51 to 53. For example, front opening unified pods (FOUPs) may be used as the carriers C.

The gate valves 61 to 68 can be opened and closed. The opening and closing of the gate valves 61 to 68 are controlled by the control device 70.

The control device 70 controls the entire processing system by performing, for example, the operations of the process chambers 11 to 14, the operations of the transfer mechanisms 21 and 41, the opening and closing of the gate valves 61 to 68, and the switching operations between the vacuum atmosphere and the atmospheric atmosphere in the load-lock chambers 31 and 32.

Next, an example of the operation of the processing system will be described. For example, the control device 70 opens the gate valve 67 and controls the transfer mechanism 41 to transfer the wafer W accommodated in, for example, the carrier C in the load port 51 to the stage 31a of the load-lock chamber 31. Then, the control device 70 closes the gate valve 67 and sets the interior of the load-lock chamber 31 to a vacuum atmospheres.

The control device 70 opens the gate valves 61 and 65 and controls the transfer mechanism 21 to transfer the wafer W in the load-lock chamber 31 to the stage 11a of the process chamber 11. Then, the control device 70 closes the gate valves 61 and 65 and operates the process chamber 11. Therefore, a predetermined process (e.g., a pre-cleaning process described later) is performed on the wafer W in the process chamber 11.

Next, the control device 70 opens the gate valves 61 and 63 and controls the transfer mechanism 21 to transfer the wafer W processed in the process chamber 11 to the stage 13a of the process chamber 13. Then, the control device 70 closes the gate valves 61 and 63 and operates the process chamber 13. Thus, a predetermined process (e.g., an embedding process described later) is performed on the wafer W in the process chamber 13.

The control device 70 may transfer the wafer W processed in the process chamber 11 to the stage 14a of the process chamber 14 configured to perform a process similar to the process in the process chamber 13. In the present embodiment, the wafer W in the process chamber 11 is transferred to the process chamber 13 or to the process chamber 14 depending on the operation status of the process chamber 13 and the process chamber 14. Thus, the control device 70 may perform a predetermined process (e.g., a ruthenium embedding process described later) on a plurality of wafers W in parallel using the process chamber 13 and the process chamber 14. As a result, it is possible to improve productivity.

The control device 70 controls the transfer mechanism 21 to transfer the wafer W processed in the process chamber 13 or 14 to the stage 31a of the load-lock chamber 31 or to the stage 32a of the load-lock chamber 32. Then, the control device 70 sets the interior of the load-lock chamber 31 or the load-lock chamber 32 to the atmospheric atmosphere. The control device 70 opens the gate valve 67 or the gate valve 68 and controls the transfer mechanism 41 to transfer the wafer W in the load-lock chamber 31 or the load-lock chamber 32 to the carrier C, for example, in the load port 53.

As described above, according to the processing system illustrated in FIG. 1, while wafers W are being processed in the respective process chambers, predetermined processes may be performed on the wafers W without exposing the wafers W to the air, that is to say, without breaking vacuum.

### <Processing Apparatus>

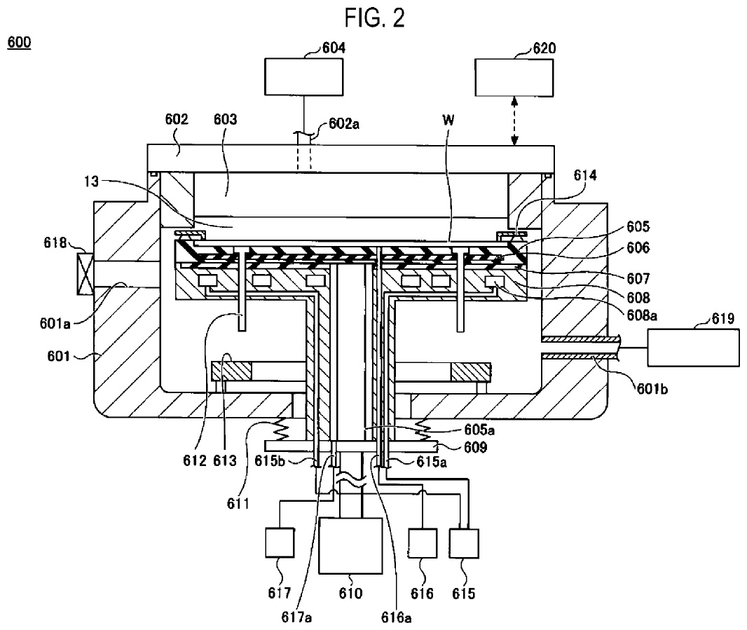

Next, an example of a structure of a processing apparatus 600 that implements a process chamber for use in an embedding method, which is a predetermined process according to an embodiment, will be described with reference to FIG. 2. FIG. 2 is a schematic sectional view of an example of the processing apparatus 600. The processing apparatus 600 illustrated in FIG. 2 is a chemical vapor deposition (CVD) apparatus, and is an apparatus that performs, for example, a ruthenium embedding process for embedding ruthenium. For example, a process gas such as a ruthenium-containing gas is supplied, and a predetermined process such as a ruthenium film forming process is performed on the wafer W. The processing apparatus 600 may have a function of performing the pre-cleaning process described later. Hereinafter, the processing apparatus 600 for use in the process chamber 13 will be described as an example.

A main body container 601 is a bottomed container having an opening at an upper portion thereof. A support member 602 supports a gas ejection mechanism 603. In addition, the support member 602 closes the upper opening of the main body container 601 such that the main body container 601 is sealed to form a process chamber 13 (see also FIG. 1). A gas supply 604 supplies a process gas such as a ruthenium-containing gas or a carrier gas to the gas ejection mechanism 603 via a supply pipe 602a penetrating the support member 602. The ruthenium-containing gas and the carrier gas supplied from the gas supply 604 are supplied from the gas ejection mechanism 603 to the process chamber 13.

A stage 605 is a member on which a wafer W is placed, and is illustrated as the stage 13a in FIG. 1. A heater 606 for heating the wafer W is embedded in the stage 605. The stage 605 includes a support 605a, which extends downward from the center of the lower surface of the stage 605 and penetrates the bottom portion of the main body container 601. One end of the support 605a is supported by a lift mechanism 610 via a lift plate 609. The stage 605 is fixed on a temperature control jacket 608, which is a temperature control member, via a heat insulating ring 607. The temperature control jacket 608 has a plate for fixing the stage 605, a shaft extending downward from the plate portion and covering the support 605a, and a hole penetrating the plate and the shaft.

The shaft of the temperature control jacket 608 penetrates the bottom portion of the main body container 601. The lower end portion of the temperature control jacket 608 is supported by the lift mechanism 610 via the lift plate 609 disposed below the main body container 601. A bellows 611 is installed between the bottom portion of the main body container 601 and the lift plate 609 such that the airtightness in the main body container 601 is maintained irrespective of the vertical movement of the lift plate 609.

When the lift mechanism 610 moves the lift plate 609 upward and downward, the stage 605 moves upward and downward between a processing position (see FIG. 2) at which the wafer W is processed, and a delivery position (not illustrated) at which the wafer W is delivered between the stage 605 and an external transfer mechanism 21 (see FIG. 1) through a loading and unloading port 601a.

Lift pins 612 support the lower surface of the wafer W and lift the wafer W from the mounting surface of the stage 605 when the wafer W is delivered between the stage 605 and the external transfer mechanism 21 (see FIG. 1). Each of the lift pins 612 has a shaft and a head having a diameter greater than that of the shaft. Through holes are formed in the stage 605 and the plate of the temperature control jacket 608, and the shafts of the lift pins 612 are inserted through the through holes. In addition, recesses for accommodating the heads of the lift pins 612 are formed in the mounting surface of the stage 605. A contact member 613 is disposed below the lift pins 612.

When the stage 605 is moved to the processing position of the wafer W (see FIG. 2), the heads of the lift pins 612 are accommodated in the recesses, and the wafer W is placed on the mounting surface of the stage 605. The heads of the lift pins 612 are engaged in the recesses, and the shafts of the lift pins 612 pass through the stage 605 and the plate of the temperature control jacket 608. The lower ends of the shafts of the lift pins 612 protrude from the plate of the temperature control jacket 608. On the other hand, when the stage 605 is moved to the delivery position (not illustrated) of the wafer W, the lower ends of the lift pins 612 are brought into contact with the contact member 613 and the heads of the lift pins 612 protrude from the mounting surface of the stage 605. As a result, the heads of the lift pins 612 support the lower surface of the wafer W and the wafer W is lifted from the mounting surface of the stage 605.

An annular member 614 is disposed above the stage 605. When the stage 605 is moved to the processing position of the wafer W (see FIG. 2), the annular member 614 comes into contact with the outer peripheral portion of the upper surface of the wafer W, and the wafer W is pressed against the mounting surface of the stage 605 by the weight of the annular member 614. On the other hand, when the stage 605 is moved to the delivery position (not illustrated) of the wafer W, the annular member 614 is engaged with an engagement portion (not illustrated) above the loading and unloading port 601a. Thus, the delivery of the wafer W by the transfer mechanism 21 (see FIG. 1) is not hindered by the annular member 614.

A chiller unit 615 circulates a coolant (e.g., cooling water) in a flow path 608a formed in the plate of the temperature control jacket 608 via pipes 615a and 615b.

A heat transfer gas supply 616 supplies a heat transfer gas (e.g., He gas) to a space between the rear surface of the wafer W placed on the stage 605 and the mounting surface of the stage 605 through a pipe 616a.

A purge gas supply 617 causes a purge gas to flow through a pipe 617a, a gap formed between the support 605a of the stage 605 and the hole in the temperature control jacket 608, a flow path (not illustrated) formed between the stage 605 and the heat insulating ring 607 and extending outward in a radial direction, and a vertical flow path (not illustrated) formed in the outer peripheral portion of the stage 605. Through these flow paths, the purge gas (e.g., CO₂ gas) is supplied to a space between the lower surface of the annular member 614 and the upper surface of the stage 605. Thus, the process gas is prevented from flowing into the space between the lower surface of the annular member 614 and the upper surface of the stage 605, thereby preventing a film from being formed on the lower surface of the annular member 614 or the upper surface of the outer peripheral portion of the stage 605.

The loading and unloading port 601a for loading and unloading the wafer W and a gate valve 618 for opening and closing the loading and unloading port 601a are provided on the side wall of the main body container 601. The gate valve 618 is illustrated in FIG. 1 as the gate valve 63.

An exhauster 619 including a vacuum pump and the like is connected to the lower side wall of the main body container 601 via an exhaust pipe 601b. The interior of the main body container 601 is evacuated by the exhauster 619 such that the interior of the process chamber 13 is set to and maintained at a predetermined vacuum atmosphere (e.g., 1.33 Pa).

A control device 620 controls the operation of the processing apparatus 600 by controlling the gas supply 604, the heater 606, the lift mechanism 610, the chiller unit 615, the heat transfer gas supply 616, the purge gas supply 617, the gate valve 618, the exhauster 619, and the like. The control device 620 may be provided independently from the control device 70 (see FIG. 1), or the control device 70 may also serve as the control device 620.

An example of the operation of the processing apparatus 600 will be described. At a start of the operation, the interior of the process chamber 13 is set to a vacuum atmosphere by the exhauster 619, and the stage 605 is moved to the delivery position.

The control device 620 opens the gate valve 618. A wafer W is placed on the lift pins 612 by the external transfer mechanism 21. When the transfer mechanism 21 goes out of the loading and unloading port 601a, the control device 620 closes the gate valve 618.

The control device 620 controls the lift mechanism 610 to move the stage 605 to the processing position. At this time, as the stage 605 moves upward, the wafer W placed on the lift pins 612 is placed on the mounting surface of the stage 605. In addition, the annular member 614 comes into contact with the outer peripheral portion in the upper surface of the wafer W, and the wafer W is pressed against the mounting surface of the stage 605 by the weight of the annular member 614.

At the processing position, the control device 620 operates the heater 606 and controls the gas supply 604 to supply the process gas such as ruthenium-containing gas or the carrier gas from the gas ejection mechanism 603 to the process chamber 12. As a result, a predetermined process such as film formation is performed on the wafer W. The gas after processing the wafer W passes through the flow path above the upper surface of the annular member 614, and is exhausted by the exhauster 619 through the exhaust pipe 601b.

At this time, the control device 620 controls the heat transfer gas supply 616 to supply the heat transfer gas between the rear surface of the wafer W placed on the stage 605 and the mounting surface of the stage 605. In addition, the control device 620 controls the purge gas supply 617 to supply the purge gas to the space between the lower surface of the annular member 614 and the upper surface of the stage 605. The purge gas passes through the flow path below the lower surface of the annular member 614, and is exhausted by the exhauster 619 through the exhaust pipe 601b.

When the predetermined process ends, the control device 620 controls the lift mechanism 610 to move the stage 605 to the delivery position. At this time, as the stage 605 moves downward, the annular member 614 is engaged with the engagement portion (not illustrated). In addition, the lower ends of the lift pins 612 are brought into contact with the contact member 613, and the heads of the lift pins 612 protrude from the mounting surface of the stage 605. Thus the wafer W are lifted from the mounting surface of the stage 605.

The control device 620 opens the gate valve 618, and the wafer W placed on the lift pins 612 is unloaded by the external transfer mechanism 21. When the transfer mechanism 21 goes out of the loading and unloading port 601a, the control device 620 closes the gate valve 618.

As described above, according to the processing apparatus 600 illustrated in FIG. 2, it is possible to perform a predetermined process such as film formation on the wafer W. Although the processing apparatus 600 having the process chamber 13 has been described, the processing apparatus having the process chamber 11, the processing apparatus having the process chamber 12, and the processing apparatus having the process chamber 14 may have the same configuration as the processing apparatus 600. Alternatively, the processing apparatus having the process chamber 11, the processing apparatus having the process chamber 12, and the processing apparatus having the process chamber 14 may have different configuration from that of the processing apparatus 600.

### <Embedding Method According to Embodiment>

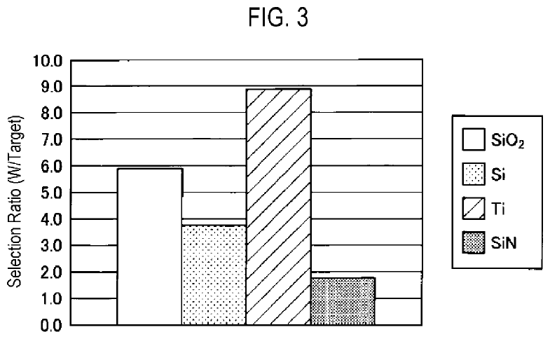

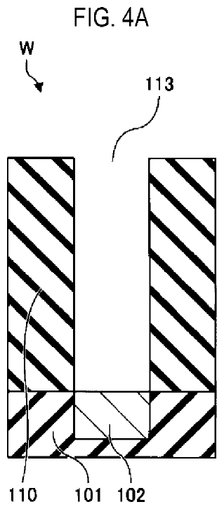

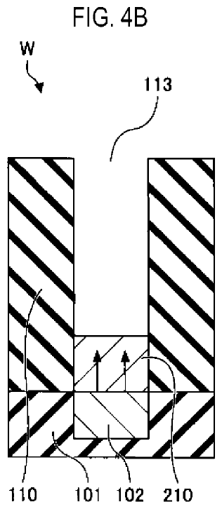

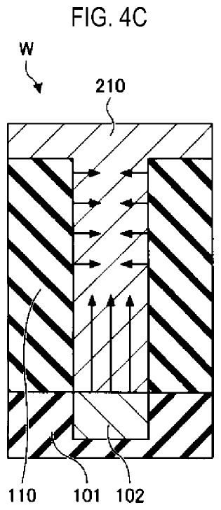

Next, a method for embedding ruthenium in a recess formed in a wafer W according to an embodiment will be described with reference to FIG. 3 and FIGS. 4A to 4C. FIG. 3 illustrates an example of selection ratios when ruthenium is embedded according to an embodiment. FIGS. 4A to 4C are schematic sectional views of a wafer illustrating respective processes of an embedding method according to the embodiment.

In FIG. 3, an example of experimental results as to an amount of a ruthenium film that could be formed on a metal film, for example, tungsten under conditions of forming a ruthenium film having a thickness of 1 nm on a silicon oxide film (SiO₂), a silicon film (Si), a titanium film (Ti), and a silicon nitride film (SiN), respectively. In FIG. 3, the amount of a ruthenium film that could be formed on tungsten under a condition of forming a ruthenium film having a thickness of 1 nm on a target material is represented as a “selection ratio”.

According to the experimental results, a ruthenium film having a thickness of about 6 nm was formed on tungsten under a condition for forming a ruthenium film having a thickness of 1 nm on a silicon oxide film. That is to say, it was found that the selection ratio is about 6.0.

In addition, a ruthenium film having a thickness of about 4.0 nm was formed on tungsten under a condition of forming a ruthenium film having a thickness of 1 nm on a silicon film. Thus, it was found that the selection ratio is about 4.0. Similarly, a ruthenium film having a thickness of about 9.0 nm was formed on tungsten under a condition of forming a ruthenium film having a thickness of 1 nm on a titanium film. Thus, it was found that the selection ratio is about 9.0. Further, a ruthenium film having a thickness of about 2.0 nm was formed on tungsten under a condition of forming a ruthenium film having a thickness of 1 nm on a silicon nitride film. Thus, it was found that the selection ratio is about 2.0.

As the selection ratio of tungsten to each of the silicon oxide film, the silicon film, the titanium film, and the silicon nitride film is larger, a ruthenium film is more easily formed on tungsten, and a ruthenium film is less easily formed on each of the corresponding materials. According to the experimental results, the corresponding materials are the titanium film, the silicon oxide film, the silicon film, and the silicon nitride film in the descending order of the selection ratio. In addition, even in the silicon nitride film having the smallest selection ratio, the selection ratio was about 2.0, which is larger than 1. Accordingly, it was found that in any of the materials, a ruthenium film is more easily deposited on tungsten than on each material, and that, even in the silicon nitride film having the smallest selection ratio, the ruthenium film is formed on tungsten at a film forming rate of about twice that on the silicon nitride film.

A method of embedding ruthenium in a recess formed in a wafer W according to the embodiment will be described with reference to FIGS. 4A to 4C using the selectivity described above.

FIG. 4A is a schematic sectional view illustrating a wafer W supplied to the processing system. As illustrated in FIG. 4A, the wafer W supplied to the processing system has an insulating film 110 deposited on a base film 101. A metal layer 102 is formed on the base film 101. As a material of the metal layer 102, a metal which does not allow ruthenium to diffuse in the metal layer 102, for example, tungsten, copper, or ruthenium may be used.

The insulating film 110 formed on the base film 101 is formed of, for example, a silicon-containing film such as a silicon oxide film, a silicon film, or a silicon nitride film. However, it is possible to select any material as the material of the insulating film 110 as long as a film forming rate of ruthenium on the metal layer 102 is higher than a film forming rate of ruthenium on the insulating film 110. The insulating film 110 is not limited to a single-layer film of a silicon oxide film, a silicon film, or a silicon nitride film, and may be any of laminated films in which different silicon-containing films are combined, such as a laminated film of a silicon oxide film and a silicon nitride film. In addition, a titanium film may be used instead of the silicon-containing film. A recess 113 such as a trench, a via hole, or a contact hole is formed in the insulating film 110, and the metal layer 102 is exposed from the bottom portion of the recess 113.

FIG. 4B is a schematic sectional view illustrating the wafer W in the middle of the ruthenium embedding process. The ruthenium embedding process is performed in the process chamber 13 or the process chamber 14 (see FIG. 1). Here, an example in which the ruthenium embedding process is performed in the process chamber 13 will be described. A silicon oxide film is taken as an example of the insulating film 110, and tungsten is taken as an example of the metal layer 102.

As the process chamber 13 in which the ruthenium embedding process is performed, for example, a CVD apparatus, an example of which is illustrated in FIG. 2, may be used. First, a ruthenium-containing gas is supplied to the process chamber 13 into which the wafer W has been loaded. For example, dodecacarbonyl triruthenium (Ru₃(CO)₁₂) is supplied to the process chamber 13, and the wafer W placed on the stage 13a is heated by the heater 606 (see FIG. 2).

A ruthenium film is formed by thermal decomposition of Ru₃(CO)₁₂ adsorbed to the surface of the wafer W. Here, in the film forming method based on the thermal decomposition of Ru₃(CO)₁₂, the film forming rate of ruthenium on the surface of the metal layer 102, i.e., tungsten, is about six times the film forming rate of ruthenium on the side surface of the insulating film 110, i.e., the silicon oxide film formed in the recess 113 (see FIG. 3). That is to say, the film forming rate of ruthenium from the side surface of the recess 113 is about 1/6 of the film forming rate from the bottom portion of the recess 113.

Using this selectivity, as indicated by arrows in FIG. 4B, ruthenium is embedded in a bottom-up fashion from the bottom portion of the recess 113 to form a ruthenium-embedded portion 210. Thus, it is possible to embed ruthenium from the bottom portion of the recess 113, which suppresses occurrence of voids and seams.

Although the ruthenium embedding process in which a film is formed using Ru₃(CO)₁₂ has been described, the ruthenium-containing gas is not limited thereto, and a gas containing Ru₃(CO)₁₂ (but not containing oxygen gas), (2,4-dimethylpentadienyl) (ethylcyclopentadienyl) ruthenium: (Ru(DMPD)(EtCp)), bis (2,4-dimethylpentadienyl) ruthenium: (Ru(DMPD)₂), 4-dimethylpentadienyl (methylcyclopentadienyl) ruthenium: (Ru(DMPD)(MeCp)), bis (cyclopentadienyl) ruthenium: (Ru(C₅H₅)₂), cis-dicarbonyl bis (5-methylhexane-2,4-dionate) ruthenium (II), bis (ethylcyclopentadienyl) Ruthenium (II): Ru(EtCp)₂, or the like may be used.

FIG. 4C is a schematic sectional view illustrating the wafer W after the ruthenium embedding process is completed. In the ruthenium embedding process, as indicated by long arrows in FIG. 4C, the ruthenium-embedded portion 210 is formed in a bottom-up fashion from the bottom portion of the recess 113. In addition, as indicated by short arrows in FIG. 4C, a ruthenium film is also gradually formed on the side surface. In this manner, the ruthenium film is gradually formed in a conformal manner while suppressing occurrence of voids and seams, whereby the ruthenium-embedded portion 210 embedded in the entirety of the recess 113 is formed.

In some embodiments, the ruthenium embedding process may use a ruthenium film forming method in which no oxygen gas is used as a gas supplied to the process chamber 13. This makes it possible to prevent the surface of the metal layer 102 on the bottom portion of the recess 113 from being oxidized by an oxygen gas.

### <Modification>

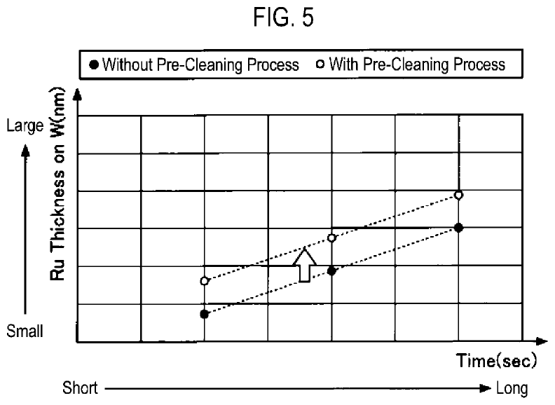

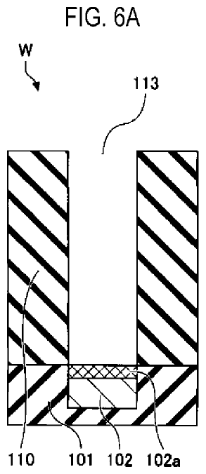

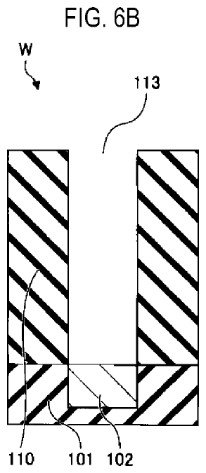

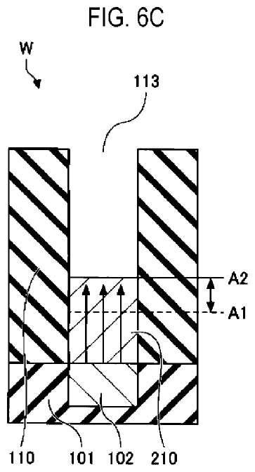

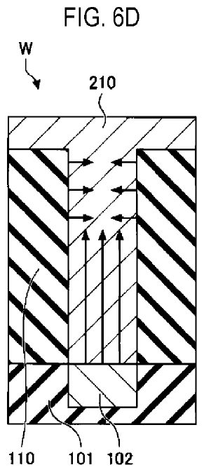

Next, an embedding method according to a modification of the embodiment will be described with reference to FIGS. 5 and FIGS. 6A to 6D. FIG. 5 illustrates presence and absence of a pre-process and an example of selection ratios according to a modification of the embodiment. FIGS. 6A to 6D are schematic sectional views of a wafer illustrating respective processes of an embedding method according to the modification to the embodiment.

In this modification, an experiment was conducted to determine how a selection ratio is affected when a pre-cleaning process was performed and when a pre-cleaning process was not performed as the pre-process of the ruthenium embedding process. FIG. 5 represents an example of experimental results.

In the experiment of FIG. 5, the metal layer 102 was tungsten, and the insulating film 110 was a silicon oxide film. The horizontal axis of FIG. 5 represents a film forming time of ruthenium, and the vertical axis represents a thickness of ruthenium formed on tungsten.

In the pre-cleaning process, a metal oxide film formed on the surface of the metal layer 102 is removed. On the surface of the metal layer 102 exposed on the bottom portion of the recess 113, for example, a metal oxide film naturally oxidized by, for example, oxygen in the atmospheric atmosphere may be formed.

Therefore, in this experiment, it was verified which difference exists in ruthenium film formation between when the metal oxide film formed on the surface of tungsten is removed in the pre-cleaning process and when the pre-cleaning process is not performed.

From the experimental results represented in FIG. 5, it has been found that the thickness of the ruthenium film formed on tungsten when the pre-cleaning process was performed was greater than that when the pre-cleaning process was not performed. The results showed the same tendency without depending on the film forming time of ruthenium. That is to say, by performing the ruthenium embedding process after removing the metal oxide film from the surface of the metal layer 102, it was possible to increase the thickness of the ruthenium film formed on tungsten to be about 1.3 to 2 times, which depends on the film forming time, as thick as that of the ruthenium film embedded without removing the metal oxide film. That is to say, it was found that it is possible to further increase the selection ratio in the ruthenium embedding process by performing the pre-cleaning process.

Therefore, in the embedding method according to the modification of the embodiment, a metal oxide film 102a formed on the surface of the metal layer 102 illustrated in FIG. 6A is removed by performing the pre-cleaning process as a pre-process of the ruthenium embedding process. The method of removing the metal oxide film 102a is not particularly limited. For example, the metal oxide film 102a may be removed by a reduction process, or may be removed by an etching process.

FIG. 6B is a schematic sectional view illustrating the wafer W after the pre-cleaning process. By performing the pre-cleaning process, it is possible to form a ruthenium film in a bottom-up fashion on the metal layer 102 from which the metal oxide film 102a has been removed.

In this modification, the pre-cleaning process is performed in the process chamber 11 (see FIG. 1). For example, an etching apparatus, a plasma CVD apparatus, or a CVD apparatus may be used as the process chamber 11 in which the pre-cleaning process is performed. The wafer W after subjected to the pre-cleaning process in the process chamber 11 is transferred to the process chamber 13 or the process chamber 14.

FIG. 6C is a schematic sectional view illustrating the wafer W in the middle of the ruthenium embedding process.

In some embodiments, the ruthenium embedding process according to this modification may use a ruthenium film forming method in which no oxygen gas is used as a gas supplied to the process chamber 13. This makes it possible to prevent the surface of the metal layer 102 on the bottom portion of the recess 113 from being oxidized again by an oxygen gas.

In the ruthenium embedding process according to the modification, as indicated by long arrows in FIGS. 6C and 6D, a ruthenium-embedded portion 210 is also formed in a bottom-up fashion from the bottom portion of the recess 113. In addition, as an effect obtained by performing the pre-cleaning process and illustrated in FIG. 5, it is possible to further increase the selection ratio in the ruthenium embedding process compared with the case in which the pre-cleaning process is not performed. As a result, the film forming rate of the ruthenium-embedded portion 210 formed in the bottom-up fashion increases. Thus, given the same embedding time, a thickness A2 of the ruthenium film formed when the pre-cleaning process schematically illustrated in FIG. 6C is performed becomes greater than a thickness A1 of the ruthenium film formed when the pre-cleaning process is not performed. This makes it possible to enhance productivity since ruthenium can be embedded in the entirety of the recess113 in a short time while suppressing occurrence of voids and seams.

### <Embedding Method According to First Comparative Example>

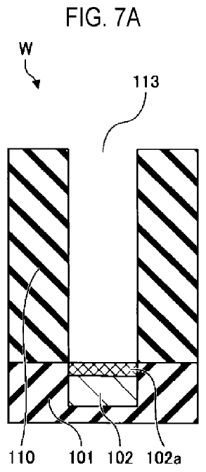

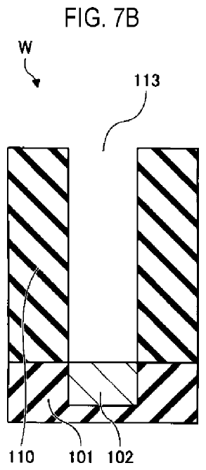

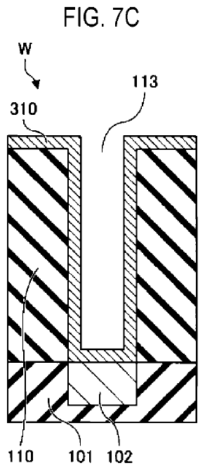

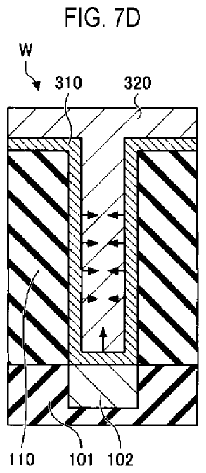

FIGS. 7A to 7D are schematic sectional views of a wafer W illustrating respective processes of an embedding method according to a first comparative example.

FIG. 7A is a schematic sectional view illustrating a wafer W supplied to the processing system. As illustrated in FIG. 7A, the wafer W supplied to the processing system has a metal oxide film 102a formed on the surface of the metal layer 102 exposed on the bottom portion of the recess 113.

FIG. 7B is a schematic sectional view illustrating the wafer W after the pre-cleaning process. In the pre-cleaning process of the first comparative example, the metal oxide film 102a of the metal layer 102 is removed.

FIG. 7C is a schematic sectional view illustrating the wafer W in the middle of the ruthenium embedding process of the first comparative example. In the ruthenium embedding process of the first comparative example, a conformal liner film 310, for example, a liner film of TaN, is formed.

FIG. 7D is a schematic sectional view illustrating the wafer W after the ruthenium embedding process of the first comparative example. As illustrated in FIG. 7D, a ruthenium-embedded portion 320 is formed by embedding the ruthenium in the recess 113 in which the conformal liner film 310 has been formed using Ru₃(CO)₁₂ in the same manner as the ruthenium embedding process according to the embodiment and the modification.

In the first comparative example described above, since the liner film 310 made of TaN having a specific resistance higher than that of ruthenium is formed, the electric resistance cannot be reduced.

In contrast, in the embedding method according to the embodiment and the modification thereto, the recess 113 is embedded with ruthenium with good coverage. In addition, the embedded ruthenium does not diffuse into the tungsten metal layer 102. Thus, it is possible to reduce the electrical resistance compared with the case of using a liner film or a barrier film containing metal having a high specific resistance.

As described above, according to the embedding method of the embodiment and the modification, it is possible to implement a low-resistance ruthenium embedding method. In addition, according to the processing system of the embodiment and the modification, it is possible to continuously perform the pre-cleaning process and the ruthenium-embedding process without breaking vacuum while the processes are performed on a wafer W by the process chambers.

The number of process chambers 11 to 14, the number of vacuum transfer chambers 20, the number of load-lock chambers 31 and 32, the number of atmospheric transfer chambers 40, the number of load ports 51 to 53, and the number of gate valves 61 to 68 are not limited to those illustrated in FIG. 1, but may be any other numbers. In the processing system, although it has been described that the ruthenium embedding process is performed in the process chambers 13 and 14, the ruthenium embedding process may be performed in the process chambers 12 to 14. By performing the ruthenium embedding processes on different wafers in parallel using a plurality of process chambers, the productivity can be improved. In addition, the process chamber 12 may be a process chamber that performs the pre-cleaning process in the same manner as the process chamber 11. From the viewpoint of productivity, the number of processing apparatuses that perform the pre-cleaning process and the ruthenium embedding process may be set arbitrarily in consideration of a system configuration.

That is to say, the number of process chambers of the present disclosure may be one, or may be two or more in some embodiments. The process chambers of the present disclosure may include a first process chamber in which the pre-cleaning process of removing a metal oxide film on the surface of the metal layer from a substrate having the metal layer on the bottom portion of the recess formed in the insulating layer, and a second process chamber in which the ruthenium embedding process of embedding ruthenium from the bottom portion of the recess. When the ruthenium embedding process is performed in two process chambers, the process chambers of the present disclosure may include the first process chamber, the second process chamber, and a third process chamber in which the ruthenium embedding process of embedding ruthenium from the bottom portion of the recess.

The process chamber of the present disclosure may be applicable to any types of apparatuses including a capacitively coupled plasma (CCP) apparatus, an inductively coupled plasma (ICP) apparatus, a radial line slot antenna (RLSA) apparatus, an electron cyclotron resonance plasma (ECR) apparatus, and a helicon wave plasma (HWP) apparatus, and the like.

According to the present disclosure, it is possible to provide a low-resistance ruthenium embedding method and a processing system.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. An embedding method comprising:
supplying a ruthenium-containing gas to a process chamber; and
embedding ruthenium in a recess, which is formed in an insulating layer formed on a substrate, starting from a bottom portion of the recess using the ruthenium-containing gas, the bottom portion of the recess having a metal layer.

2. The embedding method of claim 1, wherein a material of the metal layer is a metal material into which ruthenium does not diffuse.

3. The embedding method of claim 2, wherein the material of the metal layer is selected from a group consisting of tungsten, copper, and ruthenium.

4. The embedding method of claim 1, wherein a material of the insulating layer is a material selected such that a film forming rate of ruthenium on the metal layer is higher than a film forming rate of ruthenium on the insulating layer.

5. The embedding method of claim 1, wherein the insulating layer is a silicon-containing film or a titanium film.

6. The embedding method of claim 5, wherein the silicon-containing film is at least one selected from a group consisting of a silicon oxide film, a silicon film, and a silicon nitride film.

7. The embedding method of claim 1, further comprising removing a metal oxide formed on a surface of the metal layer before the embedding ruthenium.

8. The embedding method of claim 1, wherein the embedding ruthenium is performed without using an oxygen gas.

9. The embedding method of claim 1, wherein the ruthenium-containing gas is selected from a group consisting of a gas containing Ru₃(CO)₁₂, (2,4-dimethylpentadienyl) (ethylcyclopentadienyl) ruthenium: (Ru(DMPD)(EtCp)), bis (2,4-dimethylpentadienyl) ruthenium: (Ru(DMPD)₂), 4-dimethylpentadienyl (methylcyclopentadienyl) ruthenium: (Ru(DMPD)(MeCp)), bis (cyclopentadienyl) ruthenium: (Ru(C₅H₅)₂), cis-dicarbonyl bis (5-methylhexane-2,4-dionate) ruthenium (II), and bis (ethylcyclopentadienyl) Ruthenium (II): Ru(EtCp)₂.

10. A processing system comprising:
a first process chamber configured to remove a metal oxide film formed on a surface of a metal layer from a substrate having the metal layer on a bottom portion of a recess formed in an insulating layer;
a second process chamber configured to embed ruthenium in the recess starting from the bottom portion; and
a vacuum transfer chamber in communication with each of the first process chamber and the second process chamber through an openable and closable gate valve.

11. The processing system of claim 10, wherein respective processed executed in the first process chamber and the second process chamber are continuously performed without breaking vacuum.

12. The processing system of claim 10, further comprising a third process chamber configured to embed ruthenium in the recess starting from the bottom portion,
wherein the substrate unloaded from the first process chamber is transferred to the second process chamber or the third process chamber.

13. The processing system of claim 12, wherein respective processes executed in the first process chamber, the second process chamber, and the third process chamber are continuously performed without breaking vacuum.
